(19) United States
(12) Patent Application Publication
(10) Pub. No.: US 2021/0001429 A1
(43) Pub. Date: Jan. 7, 2021

(54) METHODS OF USING LASER ENERGY TO REMOVE PARTICLES FROM A SURFACE

(71) Applicant: ENTEGRIS, INC., Billerica, MA (US)

(72) Inventor: Troy SCOGGINS, Decatur, TX (US)

(21) Appl. No.: 16/918,789

(22) Filed: Jul. 1, 2020

Related U.S. Application Data
(60) Provisional application No. 62/869,651, filed on Jul. 2, 2019.

(51) Int. Cl. B23K 26/40; B23K 26/12; H01L 21/02

(52) U.S. Cl. CPC B23K 26/40; B08B 7/028; H01L 21/02098; B23K 26/1224

(57) ABSTRACT

Described are methods of using laser energy to remove particles from a surface, such as a porous surface, optionally without causing ablation to the surface.

### FIELD OF THE INVENTION

The following description relates to methods of using laser energy to remove particles from a surface.

### BACKGROUND

Particle contamination of surfaces, i.e., the presence of unwanted or potentially deleterious solid, small-scale particles at a surface, occurs in many fields. Many methods have been developed and are commonly used to remove particles from surfaces. One common method is by ultrasonic cleaning.

In the field of semiconductor and microelectronic device processing, particle contamination in a clean processing environment, designed to be free of particle and other types of contaminants, will reduce product yields. Various methods, equipment, and systems are used for processing semiconductor and microelectronic device substrates in clean processing environments, such as in a vacuum chamber, which should be as free as possible from particle contamination.

Examples of processes that are performed in a vacuum chamber include: processes designed to chemically modify a surface of a substrate (e.g., to “dope” a surface by implanting an impurity); or to deposit a layer of material onto a surface (e.g., by chemical vapor deposition); or to alter (e.g., remove by etching) some or all of a surface of a substrate such as by plasma treatment using controlled vacuum plasma. The vacuum chamber is part of a larger system such as an ion implantation apparatus, a vapor deposition or chemical vapor deposition (CVD) system, or a plasma chamber, among others.

Other processes for semiconductor and microelectronic device manufacturing can involve depositing, treating, or removing thin film materials relative to a semiconductor or microelectronic device substrate by use of a semiconductor processing tool. Example tools include tools adapted for thin film deposition tools, tool adapted for cleaning or etching substrate surfaces, among others.

A clean processing space is defined by many different physical components that define the space or that reside and function within the space. These structures include protective structures such as liners over an interior wall of a chamber, flow structures, apertures, barriers, support structures, among others. These different structures are made from materials that are selected to be inert and stable, and to not be a sources of undesirable particle contaminants within the clean space. Still, known materials for these structures will typically shed tiny particles into the space of the chamber, particularly during a “start-up” period of preparing the system and clean space for processing. The particle contaminants, during processing within the system, may come to rest upon a surface of a substrate being processed, as a contaminant, which adversely affects the yield of devices produced on the substrates.

Many physical structures that define a clean space or that are used in a clean space are specially fabricated for this purpose. These structures may sometimes be referred to as “shaped parts” because the parts are prepared to a particular size and shape requirements, generally with high precision. The shaped parts are often fabricated by machining methods that remove material from a larger piece (a “block”) to produce the shaped piece.

A machining process uses cutting, friction, or ablation to remove material from a larger piece, and in the process produces many very fine particles (e.g., “dust”) that can remain present at surfaces of a shaped part. The majority of these particles can be transported away from a part by vacuum, during machining. But a portion of the particles can become impacted into pores or other structure at the surface of the shaped part, making those particles very difficult to remove.

The shaped parts are made from generally stable materials that do not contain volatile materials and that are non-reactive, e.g., relatively inert to processing materials present that are present in a clean space such as a vacuum chamber. The material at a surface, or the material generally, may be porous. Examples of materials often used for shaped parts of semiconductor and microelectronic processing systems include carbon and carbonaceous materials such as graphite. Graphite is used for many articles within a vacuum chamber of ion implantation system because graphite can be purified to remove metals to less than five parts per million (5 ppm). A disadvantage of graphite is that, as mentioned, graphite can shed dust particles produced during fabrication of a shaped part, including embedded machining dust that cannot be removed by typical cleaning processes such as ultrasonic cleaning.

As metrology improves and smaller particles are able to be detected within clean spaces, designed to be free of particle contaminants, the need for improved particle removal methods is increased, because particle counts increase exponentially with decrease in size. While methods exist to remove various types of residual particles from surfaces, including surfaces used in semiconductor and microelectronic device processing, current methods are not as effective as desired.

### SUMMARY

In one aspect, the invention relates to methods of removing particles from a particle-containing surface. A method includes applying laser energy to the surface at locations that include the particles, so that the amount of laser energy is sufficient to cause the particles to separate from the surface. The surface is a porous surface and is carbonaceous or ceramic.

In another aspect the invention relates to a surface prepared by a method that includes applying laser energy to a particle-containing surface at locations that include particles. The laser energy is applied in an amount that is sufficient to cause the particles to separate from the surface. The surface is porous and is either carbonaceous or ceramic.

In another aspect the invention relates to shaped parts that include a surface as described, prepared by a method of removing particles from the surface by applying laser energy to the surface.

In another aspect the invention relates to equipment such as a semiconductor manufacturing tool or a vacuum chamber or associated system that includes a surface or a shaped part as described, having a surface that has been prepared by a method of removing particles from the surface by applying laser energy to the surface.

### BRIEF DESCRIPTION OF THE FIGURES

FIG. 1 shows features of an example method as described.

FIG. 2 shows results of an inventive method of removing particles from an example graphite surface using laser energy.

FIGS. 3A, 3B, and 3C are photographs of surfaces and surface particles.

### DETAILED DESCRIPTION

The invention relates to methods of processing a surface of an article using laser energy to remove particles from the surface. The surface may be in the form of a porous, rough, or otherwise textured surface that attracts or retains the particles at the surface. Particles are located at the surface. The particles may be very small, even microscopic-scale particles such as “dust particles.”

The surface can be any surface that includes particles in contact with the surface that might be desirably removed. The surface may be “porous,” which as used herein refers to a surface that includes pores or other non-planar surface features (i.e., “topography”) on a microscopic scale, e.g., non-planar surface features (non-planar surface deviation on a local scale) on a micron scale or a nanometer scale. Some forms of “pores” may be distributed through a thickness of the material of the surface, while other forms of “pores” may be present at a surface of the material and not below the surface. The topography particularly includes features that allow or cause particles of a comparable scale or a smaller scale to adhere to and collect at or within the non-planar surface feature. Examples of surfaces within this general meaning of the term “porous” include surfaces that on a micro-scale or a nano-scale include topography such as rough, textured, uneven, or structured features that attract or retain particles at the surface; examples include pores (rounded open or closed “cells”) of a porous material, openings present at a surface and extending below the surfaces such as three-dimensional apertures, channels, grooves, or wells; protrusions; cracks; as well as other similar microscale or nanoscale structures that attract particles and hinder or prevent removal of the particles by known particle removal techniques such as ultrasonic cleaning.

According to described methods, laser energy is applied to the surface at locations of the particles in a manner that causes the particles to be separated from the surface. The laser energy is sufficient to cause the particles to be separated from the surface, but may also be applied at a dosage (total energy level) that is sufficiently low to avoid undesired damage to the surface by ablation of the material of the surface. The term “ablation” as used herein refers to causing material to be removed from a surface made of a solid (non-liquid) material by irradiating the surface with laser energy to degrade the material to cause the material to be removed from the surface. At low laser flux, the material is heated by the absorbed laser energy and is removed by evaporation or sublimation. At high laser flux, the material is typically converted to a plasma.

According to certain examples, a method of the invention can be particularly effective to remove fine particles from a surface made of carbonaceous or ceramic material, for example a carbonaceous or ceramic material that has pores at a surface, with the particles also being made of a carbonaceous or ceramic material. The carbonaceous or ceramic material of the particles may be the same carbonaceous or ceramic material that makes up the surface, or may be a different carbonaceous or ceramic material. Often, when the particles are dust particles produced during a previous process of machining or forming the surface, the material that makes up the particles is the same carbonaceous or ceramic material as that of the surface.

In particular applications, the surface can be a surface of a component (a.k.a. “part” or “shaped part”) that is used inside of a semiconductor or microelectronic device processing system, such as within a vacuum chamber of an ion implantation system, a plasma treatment system, or a deposition chamber (e.g., for chemical vapor deposition). In other applications, the surface can be a component that resides at an interior of a semiconductor processing tool. The interior of the vacuum chamber or the semiconductor processing tool is a clean space that is kept extremely clean and as free from particle contamination as possible. Accordingly, a shaped part used at an interior of one of these structures should not be a source of particle contamination.

These parts (“shaped parts”) are commonly formed to exhibit a highly precise physical shape, physical dimension, or other precision feature. Example methods for forming the high precision parts include various machining techniques that provide a high level of precision and inter-part and intra-part uniformities. The methods begin with a block of material and remove portions of the original material by machining, grinding, cutting, or another removal technique to produce a final shaped part having a desired high precision shape and size. Example techniques (referred to collectively as “machining” techniques) include precision grinding, milling, lathing, cutting, lapping, honing, ultrasonic machining, water jet or abrasive jet machining, laser machining, electrical discharge machining, ion-beam machining, electron-beam machining, chemical machining, electrochemical machining, or the like.

During a machining process, material that is removed to form a surface of a shaped part produces small particles of the material of the block as the material is removed. The particles are often in the form of fine (microscopic) dust particles. If the particles remain present at the surface of the part when the part is installed and used in a vacuum chamber or other clean space, the particles may be shed from the surface and become disposed within the interior of the vacuum chamber or clean space as particle contamination.

Most particles produced during shaping of a surface by machining can be collected and carried away from the surface during the shaping process, e.g., by vacuum. But some amount of particles may become retained at the surface, especially if the surface includes topography at which the particles may tend to physically collect and become resistant to being removed by vacuum. A portion of an amount of particles that remain at the surface may be removed after the surface is completely formed, by a cleaning or particle removal technique such as solvent cleaning or ultrasonic cleaning. But some portion of those particles may be more strongly attracted to or more firmly trapped (mechanically) at the surface, e.g., held at the surface by a pore or other topography. Those particles are more difficult to remove and conventional techniques such as solvent cleaning, vacuum, or ultrasonic cleaning are not entirely effective.

A surface to be treated with laser energy according to the present description includes particles at a surface, such as those described herein, including particles located at topography that makes the particles difficult to remove by solvent cleaning, vacuum, or ultrasonic cleaning techniques. The particles can be from any source, and may be made of any material such as carbon, ceramic (e.g., alumina), metal, metal oxides, etc. Example particles on a surface are particles produced during formation of the surface during machining, to form the surface, although the method can be effective to remove particles derived from any source or placed on the surface in any manner. Some or all of the particles may be located within pores or at other topography on the surface that makes the particles difficult to remove by previous particle removal techniques such as solvent cleaning or ultrasonic cleaning.

The particles, whether formed during machining used to create the surface, or formed in another manner, are generally small, such as the size of dust particles that are formed during machining. The particles may have a size on a scale of microns, e.g., below 1 millimeter (1,000 microns), or below 500 microns or 100 microns, or below 50, 25, 10, 1, or 0.1 microns.

The chemical make-up (composition) or the source of particles that may be removed from a surface by application of laser energy as described is not limited. According to one exemplary use of the method to remove particles from surfaces of shaped parts formed by machining, the particles located at the surface and to be removed will typically be made of material that is the same as the material of the surface, and also the same as the material removed from the surface during shaping. For shaped parts and surfaces that are prepared by machining a carbonaceous or ceramic material, the particles at the surface, to be removed, may be made of the same carbonaceous or ceramic material that makes up the surface. However, the described methods may also be effective for removing other types of particles from a surface, such as particles made of a metal, a metal alloy, solid organic materials, plastics, etc.

The shaped part that contains particles at a surface may be made of any material, such as (but not limited to) any of a variety of solid materials known (currently or in the future) for use in preparing shape parts by a machining method. For preparing a shaped part for use at an interior of a vacuum chamber of a semiconductor or microelectronic device processing system, useful materials include materials that are relatively inert to the various processing materials and conditions (e.g., elevated temperature) present in these types of processing systems. Useful materials can also have a very low content of volatile materials that might be capable of outgassing when exposed to a vacuum, and may have pores, texture, roughness, or another type of topography at a surface that may attract or may retain particles that contact the surface.

Some specific examples of materials that are understood to be useful at an interior component of a semiconductor or microelectronic device processing system, or at an interior of a semiconductor processing tool, include ceramics and carbonaceous materials. Certain specific examples include graphite, inorganic carbonaceous material, and silicon carbide.

An “inorganic carbonaceous material” (a.k.a. “carbonaceous material,” herein, for short) refers to a solid material that is made of a major amount of carbon or that is substantially or primarily made of carbon, in non-organic form. The inorganic carbonaceous material can contain, for example, at least 50 weight percent carbon, or at least 60, 70, 80, 90, 95, or 99 weight percent carbon. The inorganic carbonaceous material contains a low or insignificant amount (e.g., less than 5, 1, 0.5, or 0.1 weight percent) of organic compounds made of carbon atoms covalently bonded to hydrogen, oxygen, or nitrogen atoms.

Some examples of inorganic carbonaceous materials may be made primarily of carbon atoms in either an amorphous or a crystalline (e.g., graphite) form, e.g., may contain at least 90, 95, 98, or 99 atomic percent carbon in either an amorphous or a crystalline form.

Other examples of inorganic carbonaceous materials may contain primarily carbon and silicon atoms, including materials referred to commonly as silicon carbide (SiC). Useful or preferred silicon carbide materials may containing least 80, 90, 95, 98, or 99 atomic percent of a total amount of silicon and carbon, and may preferably contain a low amount or not more than an insignificant amount of other materials such as oxygen or hydrogen, e.g., less than 5, 3, 1, or 0.5 atomic percent of total oxygen and hydrogen. Example forms of silicon carbide include forms that are crystalline as well as forms that area amorphous. Example silicon carbide materials may contain from 40 to 90 atomic percent carbon, from 10 to 60 atomic percent silicon, and not more than 2 or 1 atomic percent of other materials, e.g., not more than 0.5 atomic percent oxygen, hydrogen, or a combination of oxygen and nitrogen. A porous silicon carbide material may be prepared by any method, including known methods of converting graphite to silicon carbide.

An example of a ceramic material is alumina.

The surface has a roughness, pores, or other topography that attracts or retains particles at the surface in a way that makes the particles difficult to remove from the surface. For example, various forms of silicon carbide, graphite, and amorphous carbonaceous materials can have pores at a surface of the material, as well as pores present (optionally) below the surface. Particles that become located within a pore can become held in place by the pore and retained at the surface by the pores structure. Pores at a surface (or throughout a thickness of a shaped piece) may be of any effective form. Example pores, e.g., as present in graphite, silicon carbide, and other ceramic and carbonaceous materials, may be in the form of openings (a “pore” or a “cell”) having a generally rounded or curved cell structure defined by and between sidewalls (e.g., a “matrix”) composed of solid material that defines the structure of the surface, e.g., a shaped part.

A size of pores of a surface may vary depending on the surface and the design and use of the structure that includes the surface. Surfaces having an average pore size of greater than 10 microns are sometimes referred to as macroporous, while surfaces or solids having an average pore size of less than 10 microns are sometimes referred to as microporous.

Methods of the invention use laser energy to remove particles from a surface that contains the particles. The method can be performed to effectively remove a significant portion of an amount of particles that are originally present on the surface prior to surface being treated with the laser energy. The method can advantageously be performed in a manner that causes only a minimum amount of damage or no discernible damage to the surface by ablation. The method can be particularly useful for effectively removing a large portion of particles that are located at structure (topography) of the surface that attracts or retains the particles and causes the particles to be difficult to remove, including particles located within pore structures of a porous or pore-containing surface.

A method of the invention is believed to cause separation of particles from a surface by heating the surface with laser energy, without requiring ablation of the surface or the particles, and preferably without causing any significant amount of ablation of the surface or of the particles. Heating at the surface is believed to cause expansion of gases located at or near the surface, or heating and expansion of materials adsorbed on the surface. This heating can affect gases or adsorbed materials at exposed surfaces, but can also affect gases or adsorbed materials at surfaces located at interiors of pores or at any other type of topography that attracts or retains particles. The expanding gases or expanded adsorbed materials cause movement of particles at the location of the expansion, which can force the particle from the surface and separate the particles from the surface. The expanding gas creates a flow of gaseous fluid away from the surface that carries the particles away from the surface without a need for ablation of the surface material or ablation of the particles being removed.

The laser energy can be applied to the surface by any method or technique that will provide sufficient energy to cause separation of particles from the surface. By example techniques, laser energy can be in the form of a laser beam having a useful area (spot size) that is passed over the surface at a rate and for an amount of time that are effective to cause particles to be separated from the surface. The combination of laser wavelength and total exposure time at the surface (based on spot size and scan rate) can be selected to uniformly apply a total amount of laser energy to the entire surface. The total amount of the laser energy can be effective to cause separation of particles from the surface, preferably without damaging the surface, i.e., without causing more than an insignificant amount of ablation of the surface.

While some amount of ablation may be accepted for some surfaces, many types of machined parts are fabricated with requirements of high precision as to physical shape and size features. The present method is advantageously capable of effectively removing particles from the surface (e.g., removing a large portion (as measured by a “tape test”) of particles that are difficult to remove (due to topography of the surface) by other methods) without causing more than a minor or insignificant level of damage due to ablation, as measured by the amount of material removed from the surface optically, e.g., using a digital optical microscope. Useful or preferred methods may apply laser energy to a surface at a total amount of laser energy that is below a level that would remove 50 microns of material from the surface as measured using a digital optical microscope. By other example methods, the total amount of laser energy is below a level that would remove 25, 10, or 5 microns of material from the surface as measured using a digital optical microscope.

The total laser energy applied to an area of the surface is determined by a combination of factors that include the form or source of the laser energy (e.g., wavelength), the area of the applied laser energy (e.g., spot size of a laser beam), and the length of time over which the laser energy is applied (scan rate).

The method can be performed in an atmosphere that facilitates separation of the particles from the surface into an adjacent atmosphere, such as an atmosphere that is itself contains a low or very low amount (concentration) of particles. One example is a cleanroom environment, for example an ISO Class 10000 or ISO Class 1000 or better cleanroom. The laser energy can be scanned to cover the entire surface, optionally in an automated fashion with computer control, to provide complete and uniform application of a desired total amount of laser energy over an entire area of a surface. Preferred examples can automatically sweep a laser beam evenly over an entire surface from which particles are being removed by applying an approximately equal number of passes or exposure time at all locations of the surface. Optionally, a source of vacuum may be applied to the surface when applying the laser energy, to collect particles separated from the surface. In some example methods, depending on the nature of the surface and the type and amount of particles being removed, applying the laser energy to the surface may create a visible amount dust in the form of a cloud of the particles as the particles separate from the surface.

The laser energy may be of any useful form, and may be pulsed or non-pulsed. Examples of useful laser wavelengths may be in a range from 100 to 1200 nanometers (nm), e.g., in a range from about 100 up to 1064 nm or 1100 nm, or from 150 or 193 nanometers up to 514, 532, or 600 nm, among others. Shorter wavelengths with higher energies may not be necessary because the laser energy is not required to cause (and preferably avoids) ablation of the surface and the particles being removed. Example lasers may be based on any laser source structure, such as a neodymium-doped YAG (yttrium aluminum garnet) crystal.

Optionally, a method may include one or more additional processes that precede the laser energy application, or that follow the laser energy application. Example surfaces can be surfaces of a shaped part as described herein that has been processed previously (e.g., immediately beforehand) by machining in a manner that causes particles to be present at the surface. An optional process that may precede the process of applying laser energy to the surface can be a process of preparing the surface by removing relatively loose or easily removed surface particles, such as by use of vacuum, ultrasonic cleaning, or compressed air. Other optional processes of a method may include one or more other modes of preparing the surface to facilitate separation of particles from the surface by application of the laser energy application. One example, for a graphite materials, is purification of a graphite material by subjecting the graphite material to an elevated temperature in the presence of halogen-containing gas to remove impurities from the graphite. See U.S. Pat. No. 3,848,739, the entirety of which is incorporated herein by reference.

An optional process that may follow applying laser energy to the surface can be particle removal by an ultrasonic technique (a.k.a. “ultrasonic cleaning”). In some instances, ultrasonic particle removal may be capable of removing particles that may remain at a surface after applying laser energy. Ultrasonic cleaning methods and equipment generally involve exposing a particle-containing surface to high-frequency sound waves in the range between 20 and 200 kilohertz while the surface is immersed in an aqueous media. Methods and equipment for ultrasonic cleaning are known and commercially available.

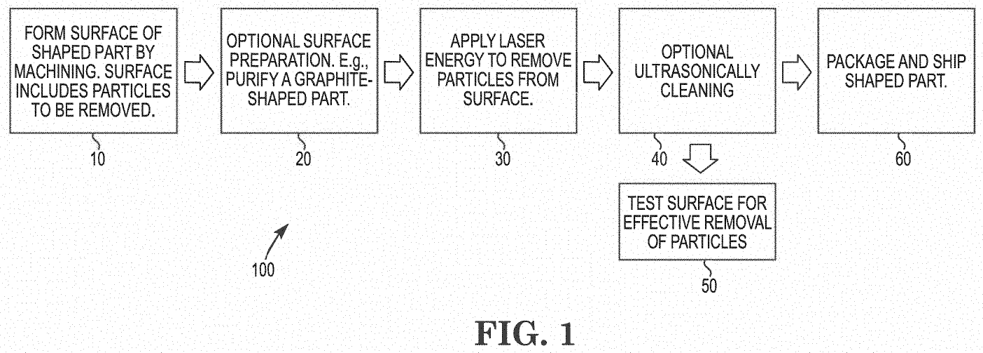

Example features of a method as described, and including certain optional processing methods, are shown at FIG. 1. A first part of the process can be to form a part that bears a surface. This is shown by example as forming a shaped part by machining (10). The part will include particle debris at a surface, including, by example, particles located inside of pores of the surface. Example surfaces and the particles may be made of ceramic or carbonaceous material. The shaped part may then be processed (20) to prepare the surface for application of laser energy (30). During application of laser energy (30), particles are separated from the surface by applying laser energy, which can heat the surface and any materials at the surface without causing ablation of the surface or of the particles being removed. Subsequent to applying the laser energy, a surface may be cleaned by ultrasonic cleaning to remove any remaining particles (40), and then the shaped part can be further processed (60) by packaging, shipping, or use of the shaped part. Optionally, the surface of the part can be tested (50) to detect the presence of and amount of particles at the surface after particle removal.

The present method can be highly effective for removing particles from a surface, including to remove particles that are difficult or impossible to remove by other common particle removal techniques such as ultrasonic particle removal techniques and solvent cleaning. The effectiveness of the present particle removal method can be assessed by known methods for measuring for the presence of particles such as “dust” particles at a surface.

By use of a tape test method, the effectiveness of a method of using laser energy to remove particles from a surface, optionally in combination with subsequent ultrasonic cleaning, can be shown to be improved as compared to alternative particle removal techniques such as ultrasonic cleaning alone. With this comparison, using a common control sample for each test, a method of removing particles by applying laser energy (alone, without ultrasonic cleaning) can remove a significantly greater amount of particles than is removed by ultrasonic cleaning techniques.

Example testing can be performed using a tape test method by applying an adhesive side of a clear tape to a surface (that contains particles) using controlled and uniform pressure followed by removing the tape from the surface in a controlled manner. The adhesive on the tape will contain particles adhered thereto that are removed from the surface. The tape can be placed on a clear glass slide and a densitometer can be used to measure opacity of the tape at an area of the tape that contains the adhered particles removed from the surface. The level of opacity relates to the amount of particles that have been removed from the surface and transferred to the tape. A higher opacity indicates more particles were present on the surface (were removed from the surface) compared to a lower opacity.

Measured using this “tape test” method, and a sample particle-containing surface that is a freshly-machined porous graphite surface (the “control” surface), the amount of particles removed from the surface by applying laser energy can be at least 50 percent of the amount of particles present at the control surface before cleaning the surface (as also measured by the same “tape test”). Preferred methods can be shown to remove at least 60, 70, 80, or 90 or 95 percent of an amount of particles initially present (i.e., present before applying laser energy) at a control surface; i.e., opacity of a tape applied to and removed from the laser-processed surface is at least 50 percent lower, preferably at least 60, 70, 80, or 90 or 95 percent lower, compared to the opacity of a tape applied to and removed from the original surface sample (control) before the laser energy is applied to the surface to remove particles from the surface.

The method can be used to effectively remove particles from any surface that includes particles to be removed, and can be especially useful for removing particles from a surface that will be used: in a clean space such as a vacuum chamber used to process a workpiece that includes a semiconductor or microelectronic device substrate or a precursor or derivative thereof, or in a clean room, or in a semiconductor tool that is in a clean room environment, or in any other environment where a very low level of particle contamination is useful or required. Example vacuum chambers may be part of a larger system such as an ion implantation system, a vapor deposition chamber (e.g., a chemical vapor deposition chamber), or a plasma chamber.

As used herein, a “microelectronic device” is a device that includes electrical circuits and related structures of very small (e.g., micron-scale or smaller) dimensions formed thereon. Example microelectronic devices include flat panel displays, integrated circuits, memory devices, solar panels, photovoltaics, and microelectromechanical systems (MEMS). A microelectronic device substrate is a structure such as a wafer (e.g., semiconductor wafer) that includes one or more microelectronic devices or precursors thereof, in a state of being prepared to form a final microelectronic device.

Examples of parts useful in a vacuum chambers, e.g., a vacuum chamber of an ion implantation system, include ceramic and carbonaceous parts that have been shaped by machining to desired dimensions (one or more of a precision length, width, or height), and optionally to include a surface feature thereon such as a groove to receive an O-ring seal, bolt holes, gas distribution holes or passages, an aperture (e.g., effective as a lens), a boss, a flange, or the like. The surface can be of a structure of an interior of a vacuum chamber referred to as a liner (protective liner) that is placed over an interior wall of a chamber sidewall, or a flow structure, a barrier, a support structure, among others.

The term “liner” refers to a substantially two-dimensional sheet or membrane (e.g., flat, planar) that has two opposed major surfaces, each extending in both a length and a width direction, with a thickness dimension between the two opposed surfaces. The magnitude of the thickness dimension is substantially less than both of the length and the width. A liner may be flexible or rigid depending on factors such as the type of material of the liner and physical features of the liner such as thickness.

### EXAMPLES

### Tape Test

Example graphite surfaces were processed for particle removal using laser energy as described herein, and using other methods for comparison.

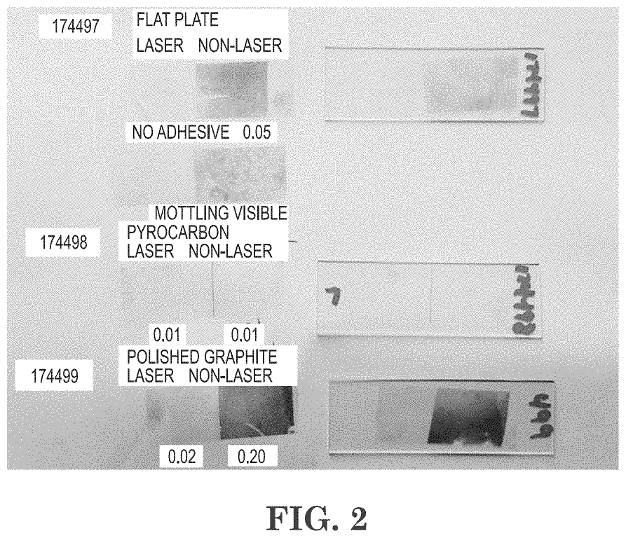

Referring to FIG. 2, Sample 1 (174497) shows a slide surface prepared during a “tape test” used to assess the presence of particles on a graphite surface that was treated using an ultrasonic cleaning method. The slide surface labeled “mottling visible” was prepared from a graphite surface that was cleaned with an ultrasonic method. The slide shows shading due to the presence of particles removed from the ultrasonically-cleaned surface, and the shading includes “mottling” (unevenness), which is typical of ultrasonically-cleaned graphite surfaces.

Sample 2 (174498) shows testing of a comparative graphite surface that is a pyrosealed graphite surface. “Pyrosealed” or “pyrocarbon” graphite surfaces are sealed by a dense pyrolytic carbon coating that covers and encapsulates surface particles, so the tape test shows no particles removed from the pyrocarbon coated surface. The opacity of the slide prepared from the surface is very low, i.e., 0.01, indicating a very low amount of particles were present on the sample surface.

Sample 3 (174499) shows testing of a graphite surface that has been treated by laser energy to remove particles. For this testing, a “polished graphite” particle-containing graphite surface was prepared for testing by purposefully impacting the surface by rubbing the surface with fine sandpaper to create a reflective surface, which produced a sample graphite surface that would have a high number of particles present at the surface. This initial (un-treated, “non-laser”) surface was tested using the tape test and an opacity value of 0.20 was measured. The surface was then treated with laser energy as described in the present patent application, to remove particles from the surface. The laser-treated surface (“Laser”) was tested using the tape test and an opacity value of 0.02 was measured.

### Scanning Electron Microscope

Amounts of particles at a surface before and after application of laser energy to remove particles can also be assessed optically by use of a scanning electron microscope (SEM).

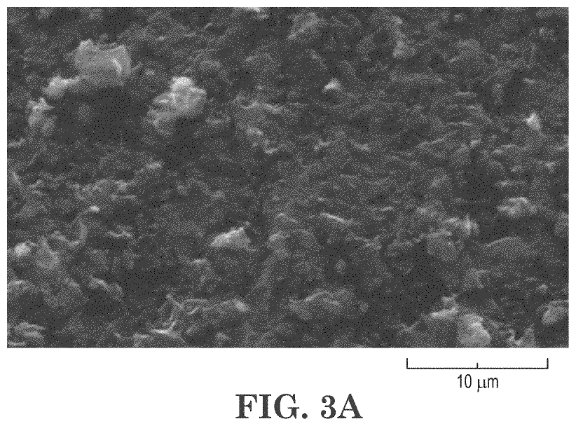

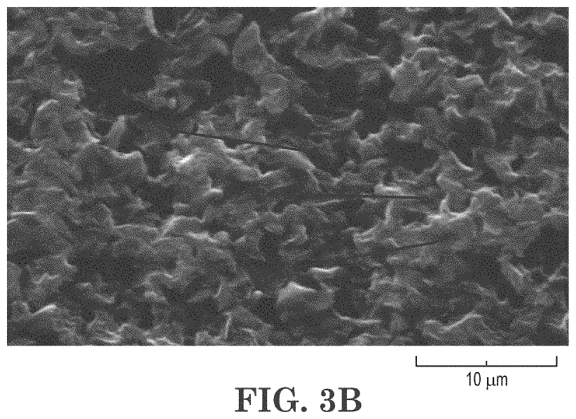

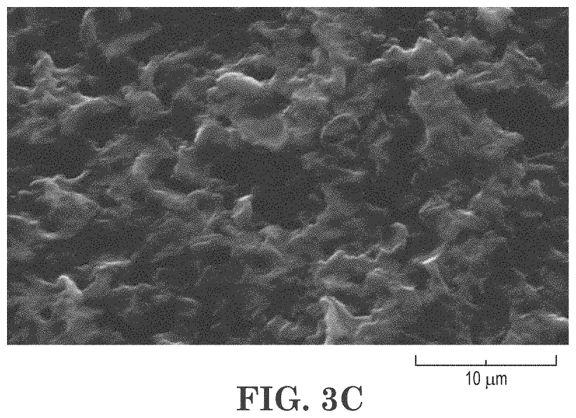

FIG. 3A is an SEM image of a particle-containing graphite surface that has not been treated by ultrasonic cleaning or by laser energy to remove the particles. Many impacted fine particles can be observed at the porous surface.

FIG. 3B shows a similar surface after the surface has been treated by ultrasonic cleaning. Particles can be identified at the porous surface (see arrows).

FIG. 3C shows a similar surface after the surface has been treated with laser energy to remove particles. The surface does not have any identifiable particles.

1. A method of removing particles from a surface, the method comprising:
applying laser energy to the surface at locations that include particles, so that an amount of applied laser energy is sufficient to cause the particles to separate from the surface, wherein the surface is porous and is either carbonaceous or ceramic.

2. The method of claim 1 wherein the particles are separated from the surface without causing substantial ablation of the surface.

3. The method of claim 1, wherein the laser energy applied is effective to reduce a measured value indicating an amount of particles at the surface, by at least 50 percent, as measured by a tape test method, compared to the surface before applying the laser energy.

4. The method of claim 1 the applied laser energy is below a level that would remove 10 microns of material from the surface as measured using a digital optical microscope.

5. The method of claim 1, wherein the surface comprises a solid matrix that defines pores and the particles are derived from material of the solid matrix.

6. The method of claim 1, wherein the surface comprises porous graphite.

7. The method of claim 1 wherein the surface comprises porous alumina.

8. The method of claim 1 wherein the laser energy has a wavelength below 1200 nanometers.

9. The method of claim 1 wherein the surface is a surface of a component of an interior of a vacuum chamber.

10. The method of claim 1 comprising, after applying the laser energy, cleaning the surface using with ultrasonic cleaning.

11. The method of claim 1 comprising forming the surface by a machining process, the particles are generated by the machining process.

12. The method of claim 1, wherein the particles comprise a carbonaceous material or ceramic.

13. The method of claim 1, wherein the particles comprise graphite.

14. A surface prepared by a method comprising: applying laser energy to a particle-containing surface at locations that include particles, so that an amount of applied laser energy is sufficient to cause the particles to separate from the surface, wherein the surface is porous and is either carbonaceous or ceramic.

15. A semiconductor manufacturing tool comprising a surface prepared by a method comprising: applying laser energy to a particle-containing surface at locations that include particles, so that an amount of applied laser energy is sufficient to cause the particles to separate from the surface, wherein the surface is porous and is either carbonaceous or ceramic.

16. A tool of claim 15 wherein the processing tool is:
a thin film deposition tool capable of depositing a thin film onto a microelectronic device substrate, or
an etching tool capable of etching a surface of a microelectronic device substrate.
